(19) United States
(12) Patent Application Publication
(10) Pub. No.: US 2026/0353612 A1
(43) Pub. Date: Nov. 5, 2026

(54) SYSTEMS AND METHODS FOR A MULTI-TANK IMMERSION COOLING ARCHITECTURE

(71) Applicant: ROSSEAU GROUP INTERNATIONAL INC., Markham (CA)

(72) Inventor: Richard MARGERISON, Georgetown, TX (US)

(21) Appl. No.: 19/488,620

(22) PCT Filed: May 30, 2024
(86) PCT No.: PCT/CA2024/050725

§ 371 Date: Nov. 27, 2025

Related U.S. Application Data
(60) Provisional application No. 63/469,612, filed on May 30, 2023.

(51) Int. Cl. H05K 7/20

(52) U.S. Cl. CPC H05K 7/20763; H05K 7/20236; H05K 7/20272

(57) ABSTRACT

Disclosed herein is an immersion cooling facility comprising at least a first immersion cooling system and a second immersion cooling system. An outflow channel is disposed to receive the cooling liquid from a trough of the first immersion cooling system, to be joined with the cooling liquid from a trough of the second immersion cooling system. The outflow channel provides a flow path for the joined cooling liquid to a cooler for cooling the cooling liquid. Also disclosed herein are various tanks, methods and devices for use in such a immersion cooling facility and such immersion cooling systems.

### CROSS-REFERENCE TO RELATED APPLICATIONS

This application claims all benefit including priority to U.S. Provisional Patent Application 63/469,612, filed May 30, 2023, and entitled “IMMERSION COOLING WITH FLOW CONDITIONING”; the entire contents of which are hereby incorporated by reference herein.

### FIELD

This disclosure relates to immersion cooling of electronic devices.

### BACKGROUND

As electronic devices (e.g., computing devices such as servers, cryptocurrency miners, etc., as well as networking devices and data storage devices connected thereto) function, some of the electricity drawn thereby is converted into heat, which tends to increase the temperature of the devices over time. In absence of suitable cooling, the devices may heat up to temperatures outside of desired operating ranges, thus rendering them to less efficient operation, shutdown, malfunction or even damage. Various cooling approaches may be used to actively keep the computers from overheating. For instance, using immersion cooling, electronic devices are submerged in a tank filled with a liquid that is thermally-conductive yet electrically non-conductive. By replacing heated liquid with cooler liquid inside the tank at a suitable rate, regulation of the temperature of the electronic devices within a desired operating range may be achieved.

However, when implemented in data centers or other high-density computing facilities, typical immersion cooling systems present efficiency and operational challenges. For example, such systems suffer from drawbacks in scaling to accommodate a large number of electronic devices.

### SUMMARY

According to an aspect, there is provided an immersion cooling system for electronic devices. The system includes a tank for immersion cooling of a plurality of electronic devices. The tank includes an intake extending proximate a bottom of the tank, for dispensing cooling liquid into the tank; an outtake extending along a top of the tank, for cooling liquid to exit the tank; wherein an electronic device is removably mountable at a position between the intake and the outtake to be immersed in the cooling liquid; and a trough extending along the tank for receiving cooling liquid exiting the tank via the outtake.

In such system, the tank may be a first tank and the system may further comprise a second tank oriented such that the trough extends along the first tank and the second tank, and wherein the cooling liquid exiting each of the first tank and the second tank is received in the trough.

In such system, the trough may extend between the first tank and the second tank.

In such system, the outtake of the first tank may be defined by a lip extending horizontally along the top of the first tank, whereby the cooling liquid exits the first tank by flowing over the lip.

In such system, the first tank and the second tank may be oriented such that the lip of the first tank and a lip of the second tank are substantially parallel and meet at the trough.

In such system, the trough may slope in a direction substantially parallel to the outtake of the tank.

In such system, the trough may include a first trough portion extending along the first tank and a second trough portion extending along the second tank.

In such system, the first trough portion may be configured to cascade flow of the cooling liquid into the second trough portion.

In such system, a pipe may extend between the first trough portion and the second trough portion for flow of the cooling liquid therein.

According to another aspect, there is provided an immersion cooling facility including a first immersion cooling system as disclosed herein, and a second immersion cooling system as disclosed herein; and an outflow channel disposed to receive the cooling liquid from the trough of the first immersion cooling system, to be joined with the cooling liquid from the trough of the second immersion cooling system, the outflow channel providing a flow path for the joined cooling liquid to a cooler for cooling the cooling liquid.

In such immersion cooling facility, a single cooler may remove heat out of the cooling liquid from the first immersion cooling system and the cooling liquid from the second immersion cooling system.

In such immersion cooling facility, the outflow channel may extend between the first immersion cooling system and the second immersion cooling system.

According to yet another aspect, there is provided a tank for immersion cooling of electronic devices. The tank includes an intake for cooling liquid to be dispensed proximate a bottom of the tank; an outtake for cooling liquid to exit proximate a top of the tank; a mount for removably mounting an electronic device to be immersed in the cooling liquid at a position between the intake and the outtake; and a diffuser for conditioning flow of the cooling liquid between the intake and the position of the electronic device.

In such tank, the diffuser may include a porous foam material.

In such tank, the diffuser may establish a tortuous path for flow of the cooling liquid from the intake to the position of the electronic device.

In such tank, the diffuser may be disposed on a bottom surface of the tank.

In such tank, at least a portion of the diffuser may be disposed beneath at least a portion of the intake.

In such tank, the intake may include an inlet oriented to dispense cooling liquid at a downward angle.

In such tank, the downward angle may be between approximately 20-90 degrees relative to a bottom surface of the tank.

In such tank, the downward angle may be between approximately 30-70 degrees relative to a bottom surface of the tank.

In such tank, the downward angle may be approximately 90 degrees relative to the bottom surface of the tank.

In such tank, the intake may include an inlet oriented to dispense cooling liquid into the diffuser.

In such tank, the intake may extend along a side wall of the tank.

In such tank, the intake may extend along a middle of the tank.

In such tank, the diffuser may be a first diffuser and the tank may further include a second diffuser, the first and second diffusers disposed on opposing sides of the intake.

According to a further aspect, there is provided an immersion cooling system for electronic devices. The system includes: a tank for receiving the electronic devices. The tank includes an intake including a plurality of inlets for dispensing for cooling liquid proximate a bottom of the tank; an outtake for cooling liquid to exit proximate a top of the tank; a first intake feed for urging cooling liquid into the intake in a first direction; and a second intake feed for urging cooling liquid into the intake in a second direction opposing the first direction; wherein convergence of cooling liquid urged into the intake by the first and second intake feeds improves uniformity of pressure among the inlets of the intake.

In such immersion cooling system, the intake may form a loop.

In such immersion cooling system, the loop may extend below the tank.

In such immersion cooling system, the loop may extend below the tank and at least one other tank.

In such immersion cooling system, the loop may extend below the tank and at least two other tanks.

In such immersion cooling system, the intake may include a pipe and the first intake feed is for urging cooling liquid in a first end of the pipe, and the second intake feed is for urging cooling liquid in a second end of the pipe.

Other features will become apparent from the drawings in conjunction with the following description.

### BRIEF DESCRIPTION OF DRAWINGS

In the figures which illustrate example embodiments,

FIG. 1 is a schematic view of an immersion cooling facility, in accordance with an embodiment;

FIG. 2 is a perspective view of a tank for immersion cooling of electronic devices, in accordance with an embodiment;

FIG. 3 is a top view of the tank of FIG. 2;

FIG. 4 is a cut-away front elevation view of the tank of FIG. 2;

FIG. 5A is a cut-away side elevation view of the tank of FIG. 2;

FIG. 5B is a cut-away side elevation view of a tank, in accordance with an embodiment;

FIG. 6 is a perspective view of an intake of the tank of FIG. 2;

FIG. 7 is a side schematic view of the intake of FIG. 6;

FIG. 8 is a top plan view of the intake of FIG. 6;

FIG. 9A and FIG. 9B each is a side schematic view of an intake and a diffuser, each in accordance with a respective embodiment;

FIG. 10A and FIG. 10B each is a side schematic view of an intake, each in accordance with a respective embodiment;

FIG. 11A is a side schematic view of an intake and a diffuser, in accordance with another embodiment;

FIG. 11B, FIG. 11C, FIG. 11D, FIG. 11E, and FIG. 11F each is a side schematic view of an intake and a diffuser, in accordance with a respective embodiments;

FIG. 12A is a top view of a tank with the intake and diffuser of FIG. 9A, in accordance with an embodiment;

FIG. 12B is a top view of a tank with the intake of FIG. 10A, in accordance with an embodiment;

FIG. 12C is a top view of a tank with the intake and diffuser of FIG. 11A;

FIG. 13 depicts an immersion cooling system with two tanks, in accordance with an embodiment;

FIG. 14 is a top plan view of the intake of the immersion cooling system of FIG. 13, in accordance with an embodiment;

FIG. 15 is a perspective view of a portion of an immersion cooling facility, in accordance with an embodiment;

FIG. 16 is a top view of a portion of the immersion cooling facility of FIG. 15, in accordance with an embodiment;

FIG. 17 is a perspective view of a portion of the immersion cooling facility of FIG. 15, in accordance with an embodiment;

FIG. 18 is a top view of a portion of the immersion cooling facility of FIG. 15, in accordance with an embodiment;

FIG. 19 is a top view of a portion of an immersion cooling facility with cascading troughs, in accordance with an embodiment;

FIG. 20A is a perspective view of a cascading trough, in accordance with an embodiment;

FIG. 20B is a magnified view of the cascading trough of FIG. 20A, in accordance with an embodiment;

FIG. 21A is a perspective view of a cascading trough, in accordance with an embodiment;

FIG. 21B is a magnified view of the cascading trough of FIG. 21A, in accordance with an embodiment; and

FIG. 22 is an elevation view of a stacked arrangement of tanks, in accordance with an embodiment.

These drawings depict example embodiments for illustrative purposes, and variations, alternative configurations, alternative components and modifications may be made to these example embodiments.

### DETAILED DESCRIPTION

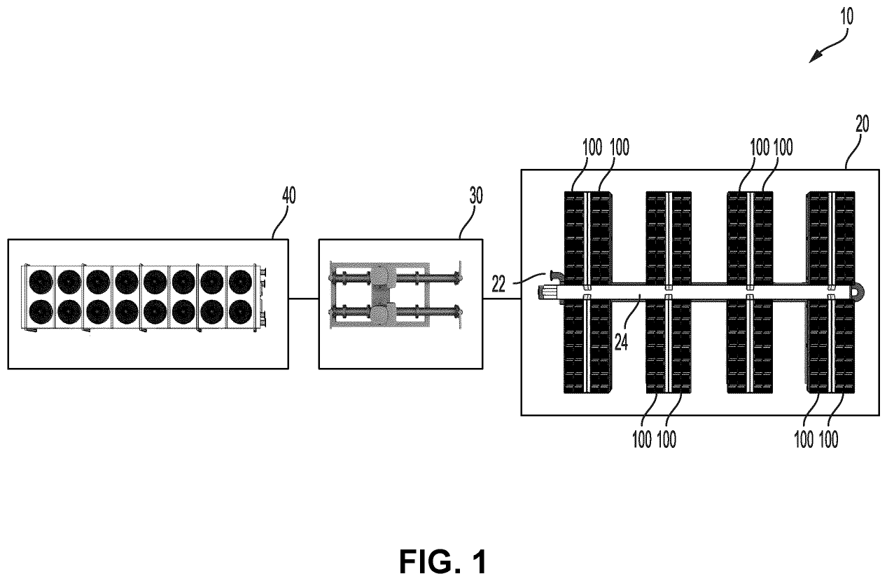

FIG. 1 is a schematic diagram of an immersion cooling facility 10 for cooling electronic devices, in accordance with an embodiment. Immersion cooling facility 10 includes a tank arrangement 20 including a plurality of tanks 100 for immersion cooling of electronic devices. Each tank 100 is configured to contain a cooling liquid and a plurality of electronic devices 50 to be immersed in the cooling liquid so that temperature of the electronic devices 50 is regulated by heat transfer into the cooling liquid.

Immersion cooling facility 10 includes a pump assembly 30 that includes one or more pumps in fluid communication with tank arrangement 20 and a cooler 40 that performs heat exchange on the cooling liquid. Operation of pump assembly 30 establishes cyclical flow of the cooling liquid within immersion cooling facility 10. In particular, pump assembly 30 urges the cooling liquid (at a desired pressure) from cooler 40 to tank arrangement 20, e.g., via pipe circuit 22 extending below tanks 100. Pump assembly 30 also urges the cooling liquid, once heated by electronic devices 50, from outflow channel 24 back to cooler 40. The cooling liquid returned to cooler 40 is cooled at cooler 40 before being returned to tank arrangement 20 in a next cycle.

Cooler 40 cools the cooling liquid, e.g., by a heat exchange process or other cooling process. In some embodiments, cooler 40 is a dry cooler. In some embodiments, cooler 40 is an adiabatic cooler. Cooler 40 may include one or more fans to assist in removing heat via air convection. In some specific embodiment, cooler 40 is a 20-fan cooler by Kelvin (Germany).

As detailed herein, immersion cooling facility 10 utilizes an architecture that allows the plurality of tanks 100 of tank arrangement 20 to interoperate with a centralized cooler 40 and pump assembly 30. This architecture provides technical effects and technical benefits. For example, in some embodiments, the need for a dedicated cooler and pump for each tank is avoided. For example, in some embodiments, cooler 40 and pump assembly 30 each provide a single point of service, and avoids distributing potential points of failure throughout a facility. In some embodiments, cooler 40 and pump assembly 30 each provide a single point of expanding for adding capacity or providing redundant capacity. For example, pump assembly 30 may include two or more pumps to provide redundancy in the event that one pump fails. Conveniently, this redundancy can be provided at a facility-level, without requiring extra pumps to be added for each tank.

In some embodiments, the disclosed architecture may improve the scalability of immersion cooling facility 10, to accommodate a large number of tanks 100 (e.g., tens, or hundreds, or more). In some embodiments, the disclosed architecture provides for economies of scale and/or efficiencies of scale, e.g., by using industrial-scale pumping and heat exchange equipment for a plurality of tanks rather than smaller-scale equipment for each tank. In some embodiments, the disclosed architecture provides surface area efficiency for heat exchange, allowing for greater heat dissipation capacity in cooler 40.

In some embodiments, the disclosed architecture may allow an immersion cooling facility 10 to include a single cooler 40 and/or a single pump assembly 30. In some embodiments, the disclosed architecture may be modularized such that a module including a single cooler 40, a single pump assembly 30, and a plurality of tanks 100 within a tank arrangement 20 is repeated throughout a cooling facility. In other words, a cooling facility may include a plurality of modules, each including a single cooler 40, a single pump assembly 30, and a plurality of tanks 100.

In some embodiments, the disclosed architecture allows a tank 100 to be swapped out for another tank 100 without disrupting the operation of cooler 40 or pump assembly 30 or the operation of other tanks 100. For example, in some embodiments, a tank 100 may be removed from tank arrangement 20 by disconnecting a pipe (or hose) between pipe circuit 22 and an immersion cooling liquid intake of tank 100, and moving the tank 100 away from outflow channel 24. A replacement tank 100 may then be added to tank arrangement 20 by connecting the pipe (or hose) between pipe circuit 22 and an immersion cooling liquid intake of replacement tank 100, and moving replacement tank 100 to be adjacent to outflow channel 24. This allows, for example, a tank 100 containing a first type of electronic devices (e.g., high-performance computing devices) to be readily replaced with a replacement tank 100 containing a second type of electronic devices (e.g., cryptocurrency mining devices), without need to change any configuration of a pump or heat exchanger.

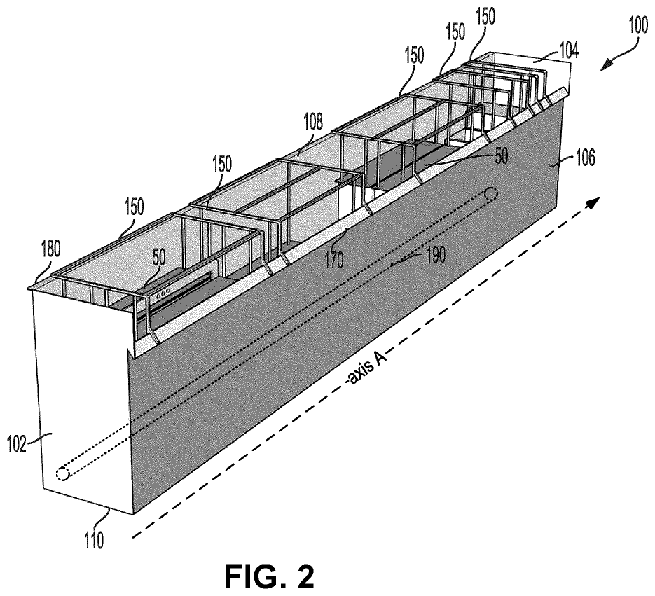

FIG. 2 depicts a tank 100 of an immersion cooling system for electronic devices, in accordance with an embodiment.

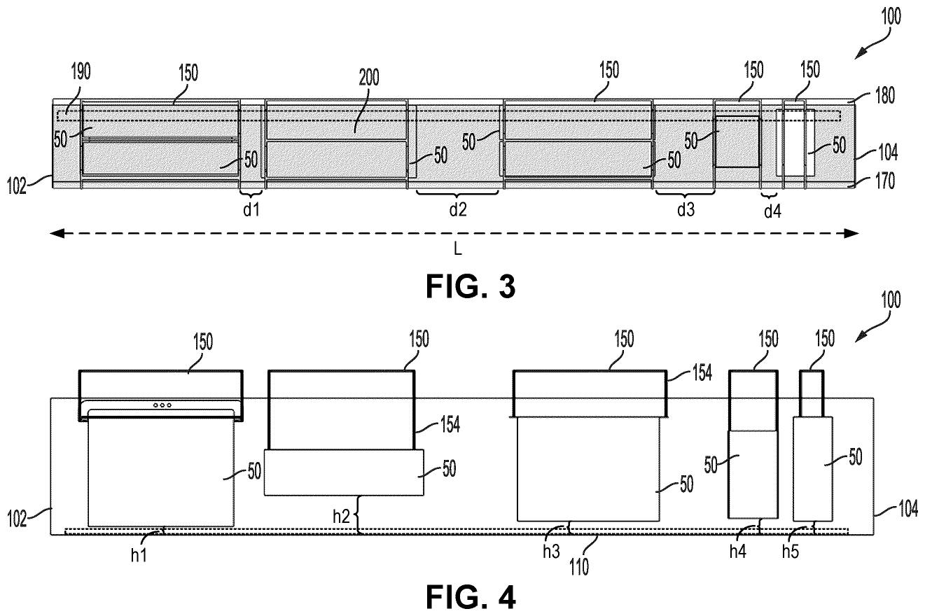

Tank 100 includes side walls 106 and 108 extending along a longitudinal axis A of tank 100. Side walls 106 and 108 are terminated at one end by an end wall 102, and at an opposite end by an end wall 104. Side walls 106 and 108 are substantially parallel to one another; end walls 102 and 104 are substantially parallel to one another. Together, side walls 106 and 108 and end walls 102 and 104, and floor 110 define a liquid-sealed container to contain a cooling liquid 200 (FIG. 3) and receive a plurality of electronic devices 50 immersed in the cooling liquid. The direction of longitudinal axis A will be referred to as a horizontal direction herein.

In the depicted embodiment, tank 100 has an open top to permit convenient addition and removal of electronic devices 50. In some embodiments, the top of tank 100 may be covered by a suitable cover, e.g., to provide protection of tank contents from debris and other unwanted elements. In some embodiments, the cover may provide a working surface and/or walking surface atop tank 100.

Tank 100 includes an intake 190 disposed proximate floor 110 at the bottom of tank 100. Intake 190 dispenses cooling liquid 200 into the bottom of tank 100. Intake 190 extends proximate side wall 108 along longitudinal axis A.

Tank 100 includes an outtake defined by a lip 170 extending horizontally along the top of side wall 106. During operation, as cooling liquid 200 is dispensed into tank 100 via intake 190, cooling liquid 200 flows upwards past (e.g., around and through) immersed electronic devices 50, and flows out of tank 100 over lip 170. In this way, lip 170 defines a maximum fill height of cooling liquid 200 within tank 100. Each of side wall 108, and rear walls 102 and 104 have a height extending higher than this maximum fill height, to prevent cooling liquid 200 from spilling over these respective walls.

Cooling liquid 200 that flows out of tank 100 over lip 170 flows to a downstream heat exchange system (e.g., cooler 40) that removes heat from cooling liquid 200, to be later pumped back into tank 100 (e.g., by pump assembly 30).

Tank 100 includes one or more mounts for mounting electronic devices to be immersed in cooling liquid 200. In the depicted embodiment, such mounts are provided by a plurality of hangers 150 which are removably mountable proximate a top of tank 100. As depicted, electronic devices 50 are removably mountable to a plurality of hangers 150. Each hanger 150 is configured to slidably rest on top of side walls 106 and 108. When hanger 150 is in this resting position, an electronic device 50 mounted thereto is suspended in tank 100 and immersed in cooling liquid 200.

As shown in FIG. 3, a hanger 150 may be rested to place a mounted electronic device 50 at a desired horizontal position along length L of tank 100. This horizontal position may be adjusted by sliding hanger 150 along the respective tops of side walls 106 and 108. Conveniently, this horizontal position may be dynamically adjusted during operation of electronic devices 50. Since hanger 150 slidably rests on the tops of side walls 106 and 108, there is no need to unfasten any fasteners to change the horizontal position of a mounted electronic device 50.

In other embodiments, other mechanisms for mounting an electronic device 50 or otherwise providing a resting position of electronic device 50 above a bottom of tank 100 (e.g., floor 110 or other bottom surface) may be provided. In such embodiments, the use of hanger 150 is optional.

The horizontal positions of electronic devices 50 may create variable horizontal spacing (e.g., d1, d2, d3, d4) between electronic devices 50. Such horizontal spacing may be selected, for example, based on an amount of heat generated by each electronic device 50, the number of electronic devices 50 to be accommodated in tank 100, the need to avoid interference (e.g., radiofrequency interference) between electronic devices 50, or other criteria.

Importantly, in the depicted embodiment, the horizontal spacing between electronic devices 50 and the horizontal position of electronic devices 50 are not constrained by mechanical features of tank 100 such as rails, slots, guides, spacers, or the like. Similarly, the horizontal size (i.e., width) of each hanger 150 may vary, to accommodate electronic devices 50 of various sizes, without such constraints.

As shown in FIG. 4, each hanger 150 extends into tank 100 to suspend a mounted electronic device 50 at a desired vertical position in tank 100. In particular, hanger 150 may have arms 154 of varying lengths to suspend electronic device 50 at the desired vertical position. For example, the vertical positions of electronic devices 50 may create variable vertical spacing between (e.g., h1, h2, h3, h4, and h5) between the respective bottoms of electronic devices 50 and floor 110. Similarly, the vertical positions of electronic devices 50 may create variable vertical spacing between the respective tops of electronic devices 50 and the fill height of cooling liquid 200. Such vertical spacing may be selected, for example, based on a desired operating temperature of an electronic device 50, an amount of heat generated by an electronic device 50, thermal properties of cooling liquid 200, and rate of flow of cooling liquid 200, or other criteria.

Importantly, in the depicted embodiment, the vertical position of electronic devices 50 is not constrained by mechanical features of tank 100 such as rails, slots, guides, spacers, or the like. Similarly, the length of each hanger 150 (e.g., length of arm 154) may vary, to accommodate electronic devices 50 of various sizes.

In some embodiments, the ability to readily accommodate electronic devices 50 of different sizes and placements within tank 100 allow a tank 100 to contain disparate types of electronic devices 50, e.g., from different vendors, having different specifications, and/or functionality, and allow changes to be made during operation of tank 100. For example, an electronic device 50 of a given type may be swapped out with another electronic device 50 of a different type, without interrupting the operation of tank 100 or other electronic devices 50 contained therein.

During operation, cooling liquid 200 is dispensed into the bottom of tank 100 via intake 190 at an initially cooler temperature. As cooling liquid 200 flows upward towards the outtake provided by lip 170, heat is transferred from electronic devices 50 into cooling liquid 200. As such, a temperature gradient may be formed whereby relatively cooler temperatures are at the bottom of tank 100 and relatively warmer temperatures are at the top of tank 100. The vertical position of a given electronic device 50 may be selected to be placed along this gradient based on an optimal working temperature range of that electronic device 50. For example, in some embodiments, the temperature gradient in tank 100 may range from approximately 20 °C and 80 °C, where the lower range is the temperature of cooling liquid 200 when dispensed into tank 100. In some embodiments, the temperature gradient in tank 100 may range from approximately 30 °C to 60 °C, again where the lower range is the temperature of cooling liquid 200 when dispensed into tank 100.

In the depicted embodiment, electronic devices 50 are suspended above floor 110. For example, electronic devices 50 may be suspended a few centimeters (e.g., 5 to 10 cm) above floor 110. Suspending electronic devices 50 in this way places the devices above intake 190.

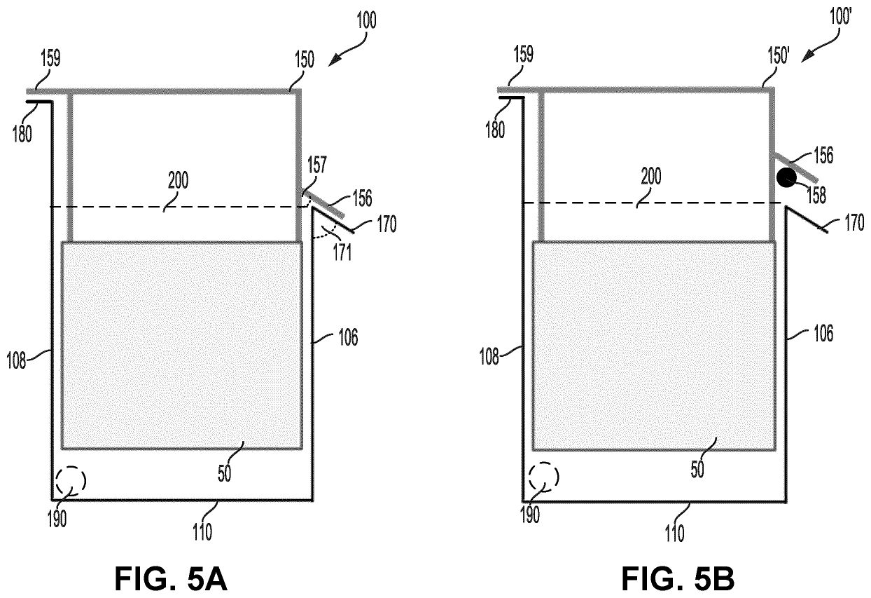

As shown in FIG. 5A, lip 170 providing an outtake of tank 100 slopes downward away from side wall 106. This slope facilitates smooth flow of cooling liquid 200 out of tank 100 and may minimize frothing of cooling liquid 200. In some embodiments, an angle 171 of this slope may be between approximately 30-70 degrees. In some embodiments, angle 171 may be between approximately 40-60 degrees. Hanger 150 includes two mounts 156 for resting on lip 170. The number of mounts 156 may vary from embodiment to embodiment, and may be fewer or greater.

In the depicted embodiment, each mount 156 extends at an angle 157 to form a v-shape for engaging the slope of lip 170. So, for example, angle 157 may be selected to substantially match angle 171. In other embodiments, mount 156 may extend substantially perpendicularly (e.g., so that angle 171 is approximately 90 degrees).

Hanger 150 also includes a mount 159 for resting on the top of side wall 108. The top of side wall 108 may include a substantially flat lip 180 to support mount 159. Lip 180 may extend the length of side wall 108.

FIG. 5B shows a tank 100′, in accordance with an embodiment. Tank 100′ includes a rail 158 extending horizontally along the top of side wall 106 between end walls 102 and 104. Rail 158 is substantially parallel to lip 170. Rail 158 is disposed to be above lip 170. Hanger 150′ includes a mount 156 for slidably resting on rail 158, above lip 170. When hanger 150′ is resting on rail 158, the flow of cooling liquid 200 over lip 170 avoids hanger 150′. Mount 156 is disposed higher on hanger 150′ compared to hanger 150. Hanger 150′ is otherwise substantially similar to hanger 150. Aside from the addition of rail 158, tank 100′ is substantially similar to tank 100.

Each electronic device 50 is a data storage device, a data processing device, a data networking device, another type of computing device, or any other type of electronic device that generates waste heat during operation. For example, electronic device 50 may be a cloud computing device, a web server, an image/video rendering server, a cryptocurrency mining device, or the like. In one specific example, cryptocurrency mining devices may include, for example, ASIC-based miners such as a Bitmain™ Antminer™ S19, or MicroBT™ Whatsminer™ M30S, or the like. Importantly, the flexible configuration of hangers 150 disclosed herein allows tank 100 to accommodate a combination of different electronic devices 50, having different operating temperature requirements, and/or having different dimensions.

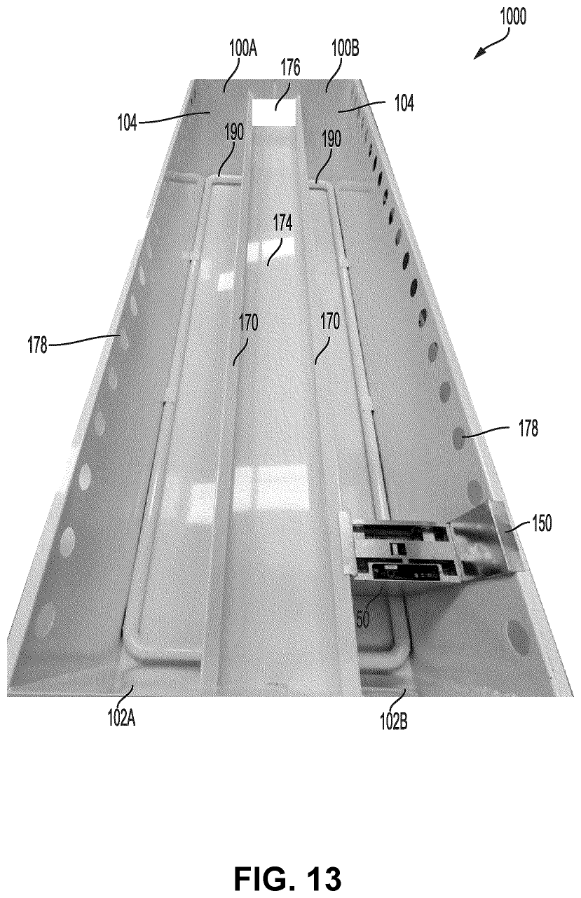

Electronic devices 50 may be wired for network access. Tank 100 may include suitable interfaces, ports, and openings, for network and/or power connections for electronic devices. For example, openings may be provided in a wall of tank 100 to provide for passage of network and/or power connections. Such openings may include, for example, openings 178 in one or both of side walls 106 and 108, which are provided above the fill height of cooling liquid 200 (FIG. 13). Such openings may, for example, prevent interference between such network and/or power connections and a cover placed over tank 100.

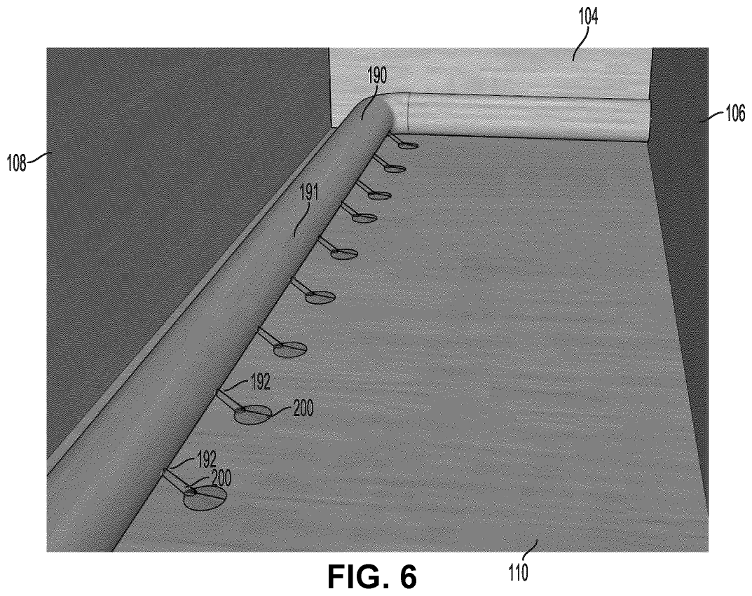

FIG. 6 shows intake 190 dispensing cooling liquid 200 into tank 100, in accordance with an embodiment. To illustrate the angle at which cooling liquid 200 is dispensed, tank 100 is shown in an initially empty state.

Intake 190 includes a pipe 191 that extends between end walls 102 and 104. Pipe 191 includes a first end proximate end wall 102 and a second end proximate end wall 104. Pipe 191 extends proximate a corner of tank 100, e.g., proximate floor 110 and side wall 108, and extends parallel to side wall 108.

In some embodiments, pipe 191 has a diameter between 5-50 mm.

In some embodiments, intake 190 dispenses cooling liquid 200 into tank 100 via pipe 191 at a rate between 50-200 gallons/minute.

As depicted, pipe 191 includes one or more inlets 192, each providing an opening (e.g., a hole, slit, or the like) through which cooling liquid 200 can be urged under pressure into tank 100. Inlets 192 are disposed to substantially span length L of tank 100 (FIG. 3). Inlets 192 are substantially evenly spaced from one another.

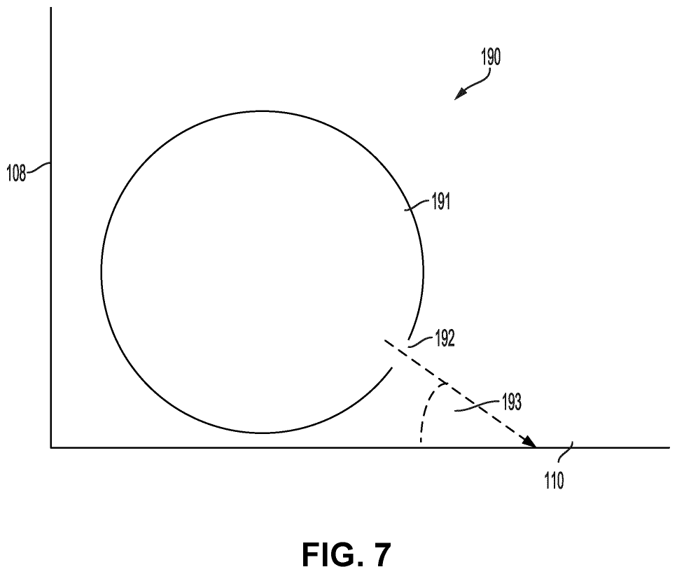

As depicted in FIG. 7, each inlet 192 is angled to provide a pressurized stream of cooling liquid 200 at a downward angle 193 towards the bottom (e.g., floor 110) of tank 100. The stream of cooling liquid 200 is substantially parallel to at least a portion of one or both of end walls 102 and 104. The streams of cooling liquid 200 impact floor 110 and spread across the bottom of tank 100 substantially towards side wall 106. In some embodiments, angle 193 is between approximately 30 and 60 degrees. In some embodiments, angle 193 is between approximately 40 and 50 degrees. In some embodiments, angle 193 is 90 degrees such that the stream of cooling liquid 200 is directed straight down towards the bottom of tank 100.

In some embodiments, inlets 192 are spaced apart by approximate 5-10 centimeters. In some embodiments, inlets 192 are spaced apart by approximately 10-20 centimeters. In some embodiments, inlets 192 are spaced apart so that multiple inlets 192 are provided below each potential horizontal position of an electronic device 50.

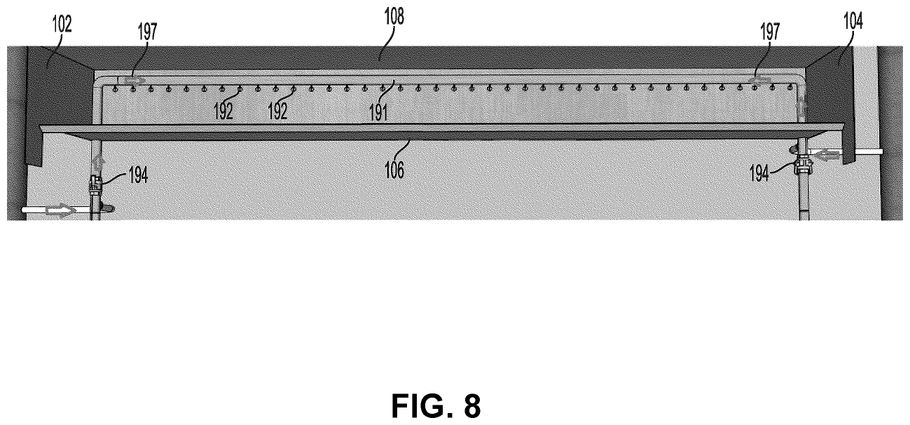

As shown in FIG. 8, thirty-nine inlets 192 are provided in tank 100. In other embodiments, the number of inlets 192 may vary, e.g., in dependence on the length L of tank 100. For example, there may be a fewer or greater number of inlets 192. The number of inlets may be selected based on, at least in part, the total flow rate of intake 190. In some embodiments, a single inlet 192 may be provided in tank 100.

Pipe 191 is in fluid communication with two intake feeds 194 providing pressurized cooling liquid 200 at each end of pipe 191. Intake feeds 194 are in turn connected to upstream distribution pipes, which are in turn in fluid communication with one or more pumps that urge cooling liquid 200 to flow from a reservoir towards intake feeds 194.

Cooling liquid 200 from the two intake feeds 194 flow via two respective flow paths into pipe 191 and opposing ends of pipe 191, and converge in pipe 191 as shown by arrows 197 (FIG. 8). This convergence in pipe 191 causes pressure equalization along pipe 191, which in turn causes cooling liquid 200 to be urged through each of inlets 192 into tank 100 at substantially equal flow rates.

As noted above, the downward angle of inlets 192 causes streams of cooling liquid 200 to impact floor 110 and spread across the bottom of tank 100. In some embodiments, because newly dispensed cooling liquid 200 is relatively cooler, it flows across the bottom of tank 100 via liquid motion effected by natural convection. Once in tank 100, warmer cooling liquid 200 moves upwards creating the temperature gradient noted above, which may also be referred to as temperature stratification.

In some embodiments, due to the combined effects of buoyancy and momentum, cooling liquid 200 dispensed from an inlet 192 moves outward radially therefrom. In such embodiments, cooling liquid 200 dispensed from each of the inlets 192 spreads out in this radial manner, and may spread to cover substantially the entire floor 110 of tank 100. In particular, when cooling liquid 200 is dispensed from a downward facing inlet 192 proximate a bottom of tank 100, it is cooler and thus denser than cooling liquid 200 already in tank 100, and thus initially sinks towards floor 110 of tank 100. Cooler cooling liquid 200 being dispensed concurrently from multiple inlets 192 creates multiple localized pools of cooler cooling liquid 200, which may expand and spread out radially to cover substantially the entire floor 110 of tank 100. As the cooler cooling liquid 200 mixes with warmer cooling liquid 200 surrounding it, it creates a more uniform temperature distribution across the bottom of tank 100. Such uniform temperature distribution is desirable for cooling devices 50 evenly, and may also help avoid hot spots within tank 100 which could impair computing device performance and efficiency.

In some embodiments, the downward angle of inlets 192 facilitates substantially even flow of cooling liquid 200 throughout tank 100 and substantially even cooling across the width and length of tank 100. This in turn provides substantially even cooling to each potential location of an electronic device 50 in tank 100. In some cases, this provides substantially even cooling to portions of each electronic device 50 in tank 100, e.g., so that each component such as particular chips receives substantially similar cooling.

Conveniently, in some embodiments, the use of perforated plates or other mechanical features to direct liquid flow towards immersed devices may be avoided.

This also avoids certain drawbacks or undesirable temperature distortions attributable to perforated plates and similar mechanical features such as, for example, requiring immersed devices to be placed at specific locations defined by the plates, decrease in cooling evenness across devices based on location relative to the plates, decrease in cooling evenness across portions of devices based on location relative to the plates, constraints on the types of devices that can be cooled based on the shapes of the plates, and so on.

In the depicted embodiments, electronic devices 50 are suspended above floor 110. This suspension ensures that electronic devices 50 do not block the streams of cooling liquid 200 entering tank 100 from impacting floor 110. Further, this suspension ensures that electronic devices 50 do not impede the spread of cooler cooling liquid 200 across the bottom of tank 100, e.g., due to natural convection.

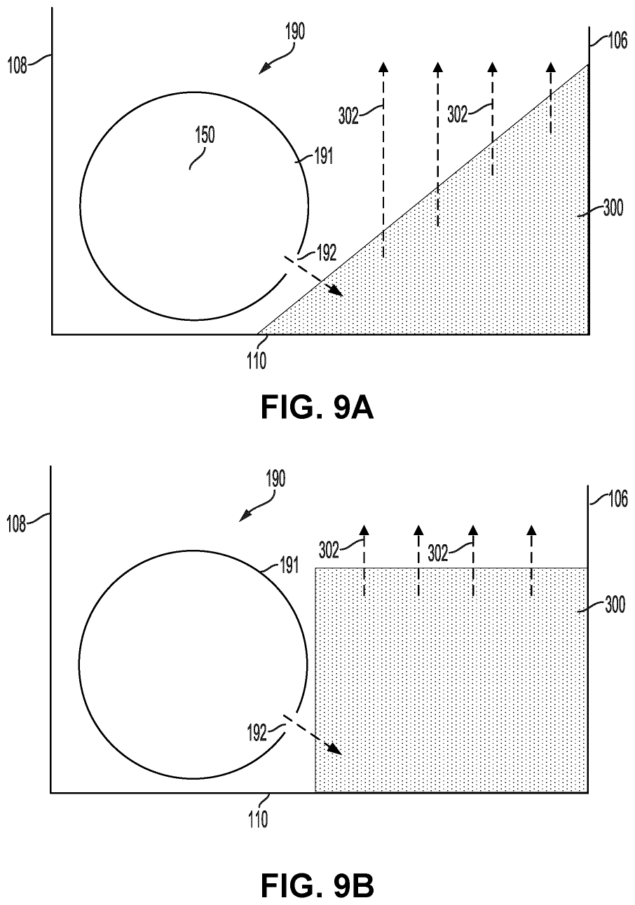

FIG. 9A illustrates intake 190 used in combination with a diffuser 300, in accordance with an embodiment. Diffuser 300 is configured to perform flow conditioning of the flow of cooling liquid 200 from intake 190 to a region of tank 100 above it, e.g., a region in which one or more electronic device(s) 50 are suspended.

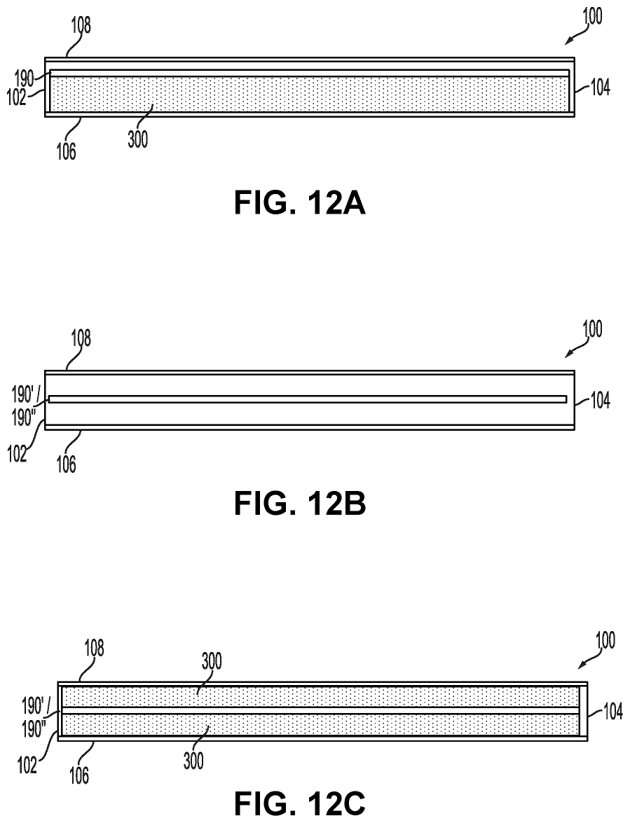

In the depicted embodiment, diffuser 300 is disposed along the bottom of tank 100 proximate pipe 191. As best seen in FIG. 12A, diffuser 300 extends along a length of tank 100. In some embodiments, diffuser 300 has a length that is at least the span of inlets 192 along pipe 191. In some embodiments, when inlets 192 span substantially the length of tank 100, diffuser 300 likewise spans substantially the length of tank 100.

In the depicted embodiment, diffuser 300 is formed of a porous open-cell foam material. The porous material, may for example, have between approximately 10-20 pores per square inch. In other embodiments, a greater or lesser density of pores may be provided, depending on desired flow characteristics of cooling liquid 200. The foam material, may for example, be a polyurethane foam. The polyurethane may, for example, be a polyether or a polyester polyurethane.

In some embodiments, diffuser 300 may be formed of another type of reticulated foam material. In some embodiments, diffuser 300 may be formed of another suitable material, e.g., capable of being formed to provide the desired tortuous flow paths and being substantially inert in the presence of cooling liquid 200. For example, in some embodiments, diffuser 300 may be formed of a suitable plastic, rubber, or other thermoplastic or elastomeric materials. In some embodiments, diffuser 300 may be formed of a suitable ceramic or metal. In some embodiments, diffuser 300 may include a combination of the above-noted materials.

As depicted, diffuser 300 is shaped as a right triangular prism with a right angle corner fitted in a corner of the bottom of tank 100, e.g., where side wall 106 meets floor 110. In this embodiment, diffuser 300 presents a triangular cross-section in the side cut-away view of FIG. 9A. In other embodiments, diffuser 300 may have a different shape. For example, in the embodiment shown in FIG. 9B, diffuser is shaped as a rectangular prism. Other possible shapes of diffuser 300 are disclosed herein. Other possible shapes will be apparent to one of ordinary skill in the art.

During operation, when cooling liquid 200 is urged out of an inlet 192, it meets diffuser 300 and has its flow conditioned thereby. In particular, when a stream of cooling 200 liquid from inlet 192 meets diffuser 300, a substantial portion of the stream enters diffuser 300 via its open pores. Cooling liquid 200 entering diffuser 300 travels through various tortuous paths formed by a network of open pores, with a substantial portion emerging out of the top surface of diffuser 300, forming a smoother upward flow 302.

In some embodiments, tortuous paths may be provided by a different structure within diffuser 300 such as a mesh structure, a honeycomb structure, or the like. The tortuous paths may create energy loss in the flow of cooling liquid 200, e.g., due to increased friction and/or collision of cooling liquid 200 with various surfaces within diffuser 300.

In some embodiments, the torturous paths cause flows of cooling liquid 200 to become impeded along many points as cooling liquid 200 makes contact with exterior portions and interior portions of the diffuser 300, resulting in various flows impacting one another, substantially colliding with each other, and interrupting each other. These interruptions and collisions cause an initially approximately horizontal flow along the bottom of tank 100 to change direction to travel vertically at various points along the bottom of tank 100. As a consequence of these interruptions and collisions, overall distribution of cooler cooling liquid 200 flowing along the bottom of tank 100 becomes more uniform.

In some embodiments, the torturous paths contribute to the creation of eddies, e.g., the bottom of tank 100 in regions beneath, beside and/or within diffuser 300. This in turn contributes to the mixing of cooling liquid 200 and the distribution of cooler cooling liquid 200 at the bottom of tank 100.

In some embodiments, as a result of flow conditioning performed by diffuser 300, upward flow 302 of cooling liquid 200 may be smoother (e.g., with less turbulence and/or fewer eddies in regions above diffuser 300), and as upward flow 302 rises above diffuser 300 may be more laminar in its characteristics compared to embodiments without diffuser 300. In some embodiments, smoother upward flow 302 may be characterized by a lower Reynolds number. In such embodiments, smoother upward flow 302 may be characterized by lower overall energy. In some embodiments, smoother upward flow 302 may be characterized by reduced velocity, including reduced lateral velocity corresponding to straightened flow.

Conveniently, in some embodiments, smoother upward flow 302 of cooling liquid 200 may reduce the occurrence of hotspots within tank 100.

In the depicted embodiment, diffuser 300 effects flow conditioning without significantly changing the flow rate (e.g., gallons per minute) of cooling liquid 200 through tank 100.

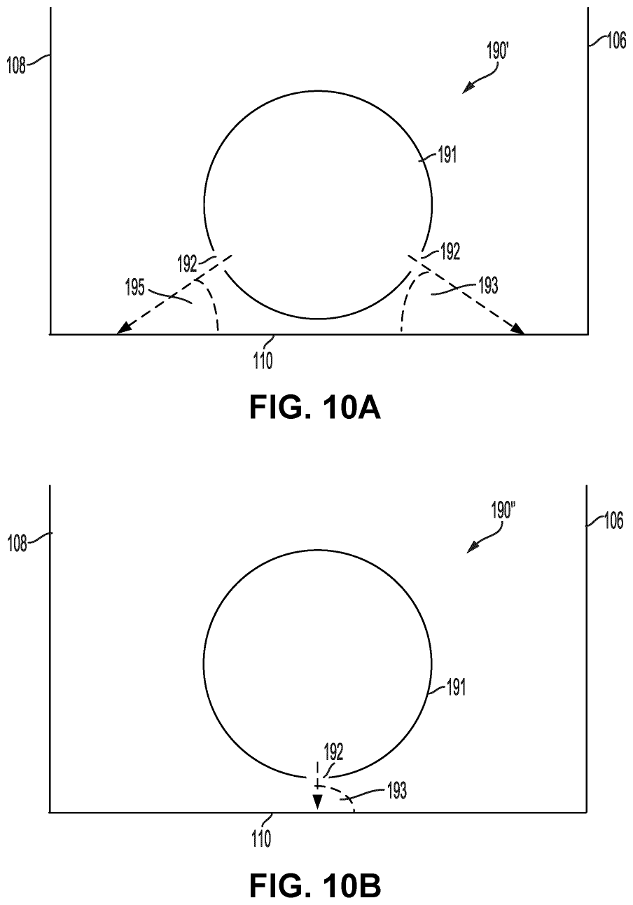

FIG. 10A depicts an intake 190′ for dispensing cooling liquid 200 into tank 100, in accordance with another embodiment. Intake 190′ may be used in place of intake 190.

As depicted, intake 190′ includes a pipe 191 that is disposed centrally along the bottom of the tank 100. In this way, intake 190′ differs from intake 190, in which pipe 191 is disposed proximate a side wall of tank 100 (e.g., proximate side wall 108 as depicted in FIG. 6, or alternatively, proximate side wall 106). As best seen in FIG. 12B, pipe 191 may be disposed to extend along the length of tank 100 at the middle of tank 100, e.g., approximately equidistant from side walls 106 and 108.

Referring again to FIG. 10A, pipe 191 includes two sets of inlets 192: a first set oriented towards side wall 106, and a second set oriented towards side wall 108.

The first set of inlets 192 may be angled to each provide a pressurized stream of cooling liquid 200 at a downward angle 193 towards the bottom (e.g., floor 110) of tank 100. These streams of cooling liquid 200 impact floor 100 and spread across the bottom of tank 100, substantially towards side wall 106. On the other side of pipe 191, the second set of inlets 192 may be angled to each provide a pressurized stream of cooling liquid 200 at a downward angle 195 towards the bottom (e.g., floor 110) of tank 100. These stream of cooling liquid 200 impact floor 100 and spread across the bottom of tank 100, substantially towards side wall 108. Angle 193 may be an angle as described above. In some embodiments, angle 195 may be a similar or the same magnitude as angle 193. In some embodiments, angle 193 and angle 195 may differ in magnitude.

In intake 190′, the sizing and spacing of inlets 192 may be configured to provide a rate and pressure for dispensing cooling liquid 200 similar to intake 190.

FIG. 10B shows an intake 190″ for dispensing cooling liquid 200 into tank 100, in accordance with another embodiment. Intake 190″ may be used in place of intake 190.

Similar to intake 190′, intake 190″ includes a pipe 191 that is disposed centrally along the bottom of the tank 100. As best seen in FIG. 12B, pipe 191 may be disposed to extend along the length of tank 100, approximately equidistant from side walls 106 and 108.

As depicted, in intake 190″, downward angle 193 of inlet 192 is approximate 90 degrees such that the stream of cooling liquid 200 is directed approximately straight down towards the bottom of tank 100. In some embodiments, the stream of cooling liquid may be substantially parallel to at least a portion of one or both of side walls 106 and 108. In some embodiments, the stream of cooling liquid may be substantially perpendicular to at least a portion of the bottom (e.g., floor 110) of tank 100. In embodiments of intake 190″, inlet 192 may be disposed at the center of a bottom of pipe 191. During operation, the streams of cooling liquid 200 impact floor 110 and spread across the bottom of tank 100, substantially towards side walls 106 and 108.

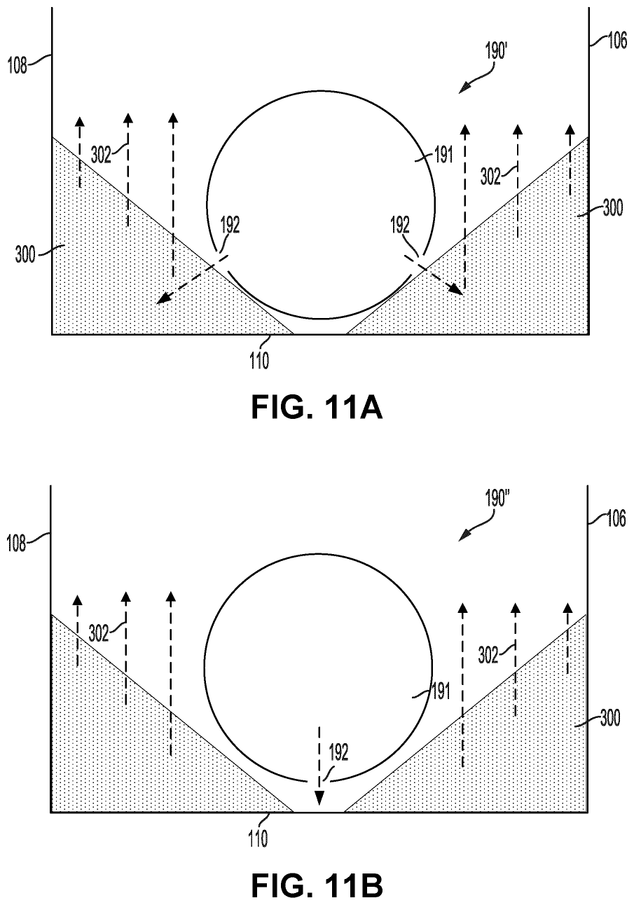

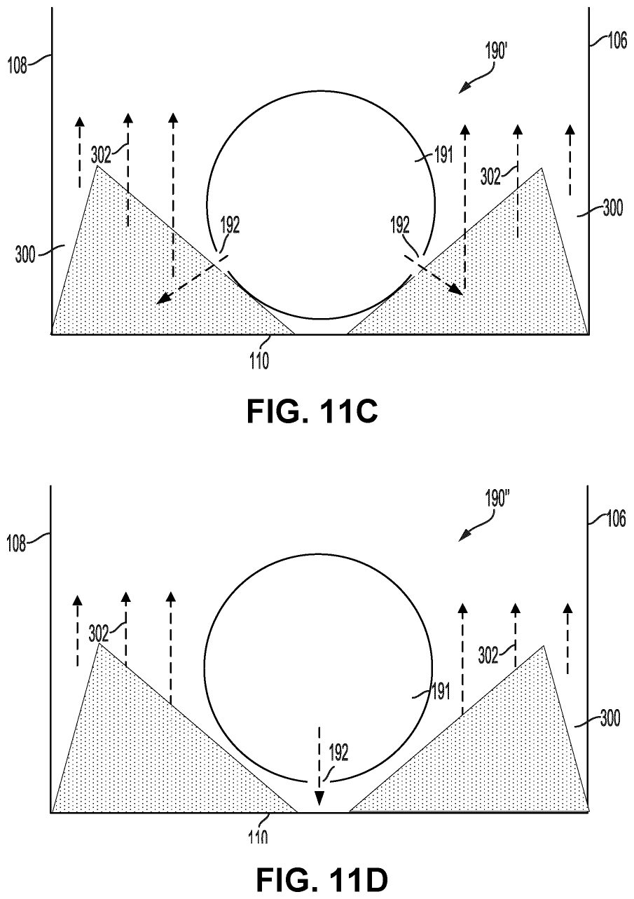

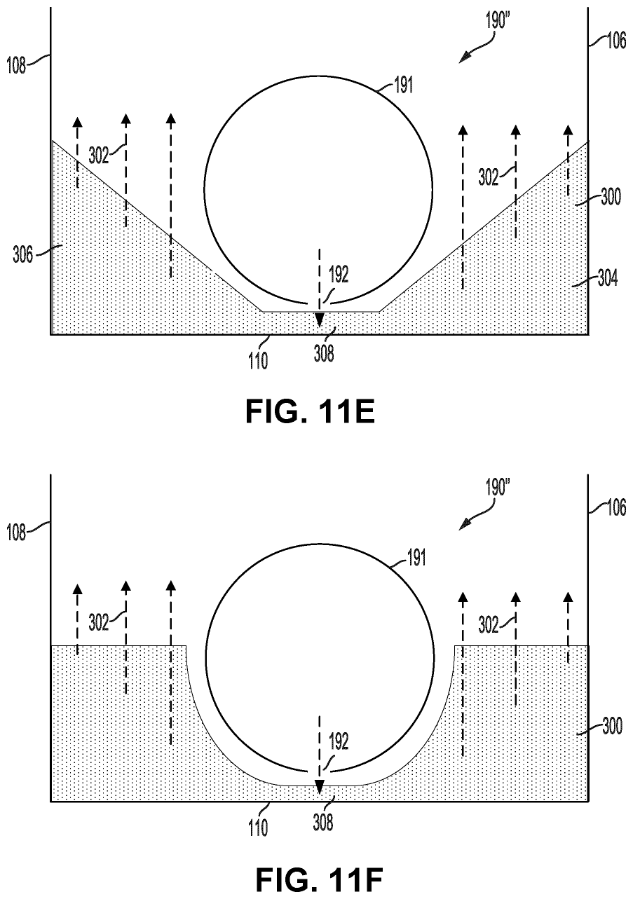

FIG. 11A shows intake 190′ and two diffusers 300 disposed in a tank 100, in accordance with an embodiment. Both diffusers 300 are disposed along a bottom of tank 100 proximate pipe 191 on opposite sides thereof. In particular, one diffuser 300 is on a right side of pipe 191 proximate side wall 106; and one diffuser 300 is on a left side of pipe 191 proximate side wall 108. As best seen in FIG. 12C, each of the two diffusers 300 extends along a length of tank 100.

During operation, when cooling liquid 200 is urged out of an inlet 192 oriented towards side wall 106, it meets diffuser 300 disposed proximate side wall 106. Similarly, when cooling liquid 200 is urged out of an inlet 192 oriented towards side wall 108, it meets diffuser 300 disposed proximate side wall 108. In both cases, the streams of cooling 200 liquid from inlet 192 meets diffuser 300 and a substantial portion enters diffuser 300. Cooling liquid travels through diffusers 300 and in manners disclosed herein, forming a smoother upward flow 302.

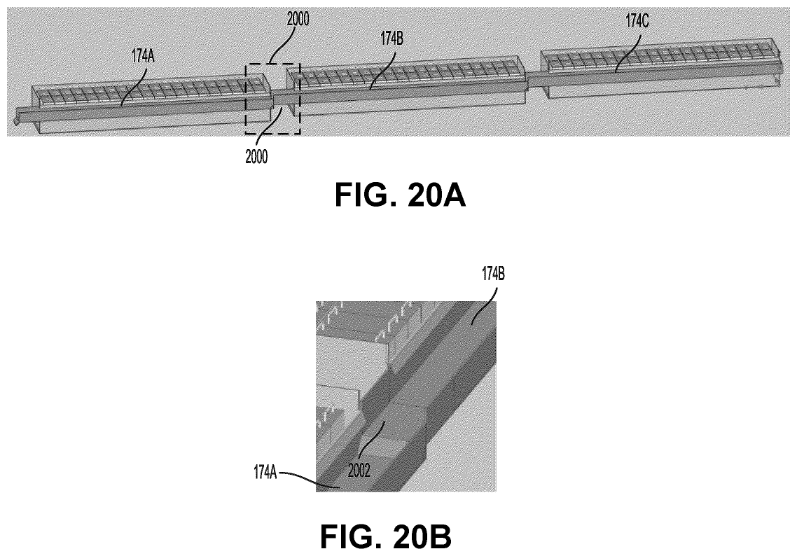

FIG. 11B shows intake 190″ and two diffusers 300 disposed in a tank 100, in accordance with an embodiment. Like the embodiment depicted in FIG. 11A, diffusers 300 are disposed along a bottom of tank 100 proximate pipe 191 on opposite sides thereof. In particular, one diffuser 300 is on a right side of pipe 191 proximate side wall 106; and one diffuser 300 is on a left side of pipe 191 proximate side wall 108. As best seen in FIG. 20C, each of the two diffusers 300 extends along a length of tank 100.

FIG. 11C shows intake 190′ and two diffusers 300 disposed in a tank 100, in accordance with another embodiment. This embodiment is similar to the embodiment depicted in FIG. 11A, with the difference that diffuser 300 disposed on the left side of pipe 191 includes a surface sloping away from sidewall 108 and diffuser 300 disposed on the right side of pipe 191 includes a surface sloping away from sidewall 106. This provides a gap between at least a portion of diffuser 300 and a respective sidewall 106 and 108.

FIG. 11D shows intake 190′ and two diffusers 300 disposed in a tank 100, in accordance with another embodiment. This embodiment is similar to the embodiment depicted in FIG. 11B, with the difference that diffuser 300 disposed on the left side of pipe 191 includes a surface sloping away from sidewall 108 and diffuser 300 disposed on the right side of pipe 191 includes a surface sloping away from sidewall 106. This provides a gap between at least a portion of diffuser 300 and a respective sidewall 106 and 108.

During operation, when cooling liquid 200 is urged out of inlet 192, a stream of cooling liquid 200 impacts floor 110, and spreads to meet diffusers 300 on either side, i.e., proximate side walls 106 and 108, respectively. A substantial portion of the stream of cooling liquid 200 enters diffusers 300. Cooling liquid 200 travels through diffusers 300 and in manners disclosed herein, forming a smoother upward flow 302.

FIG. 11E shows intake 190″ and diffuser 300, in accordance with another embodiment. In this embodiment, diffuser 300 extends between sidewalls 106 and 108. Diffuser 300 also extends along opposite sides of pipe 191. In particular, a portion 304 of diffuser 300 extends along a right side of pipe 191 and a portion 306 of diffuser 300 extends along a left side of pipe 191. Portions 304 and portion 306 are joined by a middle portion 308 that extends below pipe 191. In contrast to the embodiment depicted in FIG. 11B, a single diffuser 300 may be used. In some embodiments, diffuser 300 may be formed of unitary construction.

Each of portions 304 and 306 may be shaped as a right triangular prism. Portion 308 may be shaped as a rectangular prism.

FIG. 11F shows intake 190″ and diffuser 300, in accordance with yet another embodiment. In this embodiment, diffuser 300 is shaped to contour around at least a portion of pipe 191. As depicted, diffuser 300 may have a curved surface shaped to be complementary to an exterior shape of pipe 191.

Except as otherwise disclosed herein, intakes 190′ and 190″ are substantially similar to intake 190.

FIG. 13 depicts an immersion cooling system 1000, in accordance with an embodiment. As depicted, immersion cooling system 1000 includes two tanks 100, identified as tank 100A and tank 100B. The two tanks 100 are oriented such that lip 170 of tank 100A and lip 170 of tank 100B are substantially parallel and meet at a trough 174 extending between the tanks. Tanks 100A and 100B are substantially the same length.

Trough 174 receives cooling liquid 200 flowing over lip 170 of tank 100A and cooling liquid 200 flowing over lip 170 of tank 100B. In the depicted embodiment, trough 174 is substantially flat. Cooling liquid 200 flowing into trough 174 forces cooling liquid 200 already in trough 174 along trough 174 and out of an opening 176 in common end wall 104. In other embodiments, trough 174 may slope in a direction substantially parallel to these lips 170 towards opening 176. Cooling liquid 200 flows through opening 176 flows to a downstream heat exchange system (not shown) that removes heat from cooling liquid 200, and to a reservoir to be later pumped back into system 1000.

In some embodiments, as cooling liquid 200 falls from lip 170 into trough 174, aeration of cooling liquid 200 is provided. In particular, cooling liquid 200 falling into trough 174 provides aeration by creating air bubbles. This aeration may promote passive cooling of cooling liquid 200. For example, introduction of bubbles may increase the surface area available for heat transfer, allowing more efficient dissipation of heat to cooler ambient air. Further, the presence of air bubbles may disrupt fluid flow, inducing turbulence. Turbulence may enhance heat transfer by promoting convective mixing, thereby facilitating faster cooling.

In some embodiments, certain components of immersion cooling system 1000 may be separately fabricated and assembled on site while minimizing or avoiding use of fasteners to join such components. For example, each of tanks 100A, 100B, and trough 174 may be separately fabricated. Tanks 100A and 100B may be fabricated to include portions of intake 190 ready for interconnection.

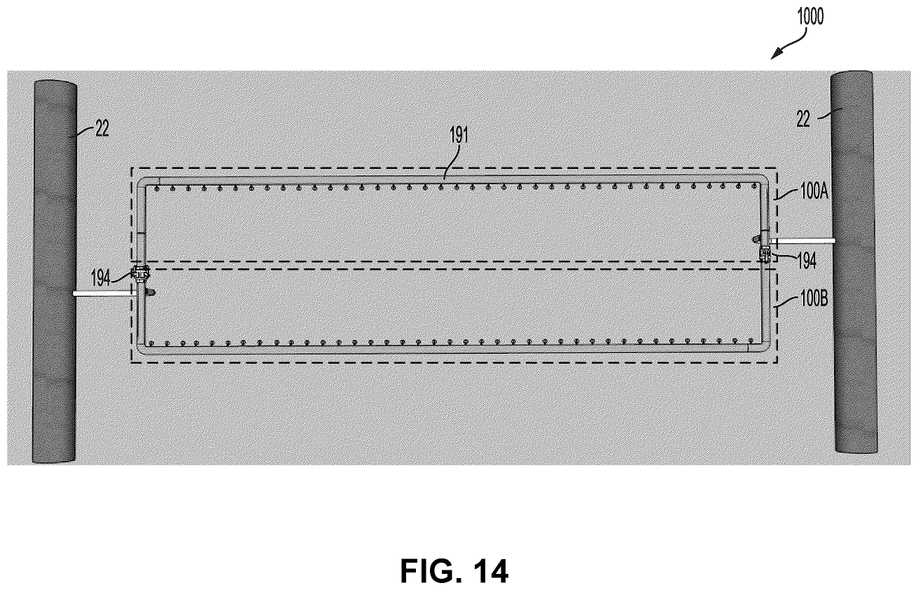

As shown in FIG. 14, intake 190 of tank 100A and intake 190 of tank 100B include a pipe that forms a loop extending through both tanks 100A and 100B. Pressurized cooling liquid 200 from pipe circuit 22 (FIG. 1) is provided to this loop via the two intake feeds 194. In other words, tanks 100A and 100B share intake feeds 194, which provide two flow paths of cooling liquid 200 into intake 190 of each tank. This loop may be referred to herein as an intake loop.

During operation, if either tank 100A or tank 100B is not operational, then one half of the intake loop can be sealed against flow of cooling liquid 200. Cooling liquid 200 would then only flow in an unsealed half of the intake loop.

In the depicted embodiment, the intake loop extends below tank 100A and 100B with one half of the intake loop extending beneath each tank. In some embodiments, an intake loop may extend below only one tank such that separate intake loops extend below tank 100A and tank 100B respectively. In some embodiments, an intake loop may extend below a greater number of tanks (e.g., three or more tanks).

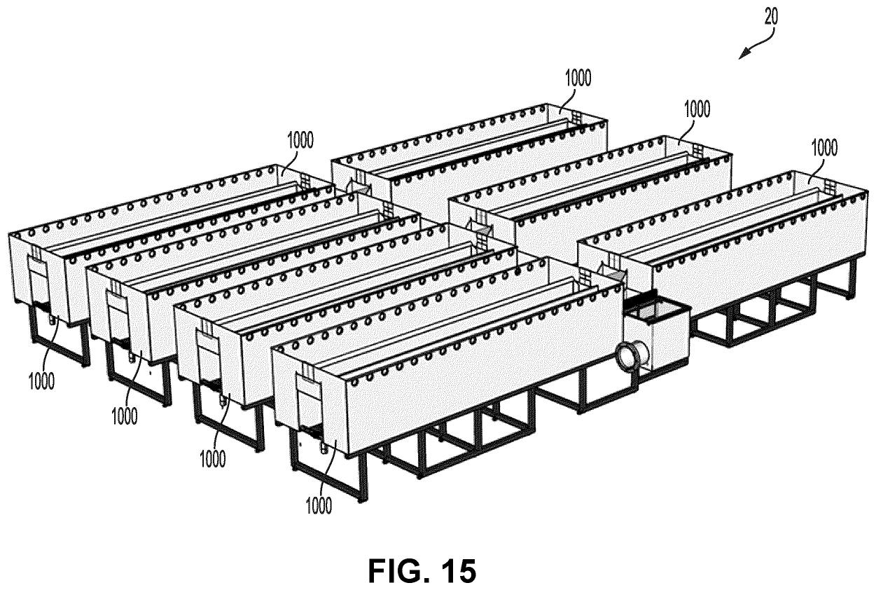

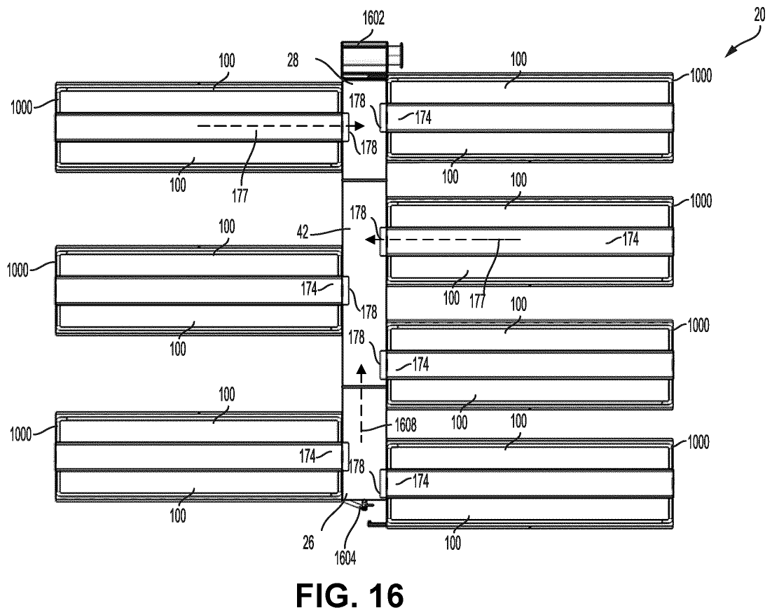

FIG. 15 and FIG. 16 depict a portion of a tank arrangement 20 of an immersion cooling facility 10 for concurrently cooling a large number of electronic devices 50. Tank arrangement 20 includes a plurality of immersion cooling systems 1000 each in fluid communication with outflow channel 24. The plurality of immersion cooling systems 1000 discharges cooling liquid 200 into outflow channel 24. As depicted, each immersion cooling system 1000 includes two tanks 100. However, in some embodiments, each immersion cooling system 1000 includes a fewer number (e.g., one) or a greater number of tanks 100.

As best seen in FIG. 16, outflow channel 24 extends between a closed end 26 and an open end 28. Closed end 26 inhibits flow of cooling liquid 200. Open end 28 includes an outtake 1602 for removing cooling liquid 200 from outflow channel 24. Outflow channel 24 defines a flow path (in direction 1608) for cooling liquid 200 discharged from each of the immersion cooling system 1000 towards an outtake 1602.

As depicted, the plurality of immersion cooling systems 1000 are arranged in two columns. In each column, immersion cooling systems 1000 are arranged so that all tanks 100 are substantially parallel to one another. Further, in each column, the tanks are lined up so that end wall 104 of each tank 100 meets outflow channel 24. As best seen in FIG. 16, immersion cooling systems 1000 are also arranged so that a lip 178 extending from opening 176 of each immersion cooling systems 1000 overhangs the top of outflow channel 24. Lip 178 is slanted to facilitate downward fluid flow. Lip 178 includes side walls to guide fluid flow. Lip 178 guides cooling liquid 200 flowing through opening 176 into outflow channel 24. In some embodiments, falling of cooling liquid 200 from lip 178 into outflow channel 24 may provide aeration of cooling liquid 200, which may facilitate cooling of cooling liquid 200.

Optionally, at least some of immersion cooling systems 1000 may be placed to be staggered so that two immersion cooling systems 1000 on opposing sides of outflow channel 24 do not discharge cooling liquid 200 into the same location of outflow channel 24.

Optionally, end 26 may include an intake 1604 for urging cooling liquid 200 from cooler 40 or a reservoir (not shown). Cooling liquid 200 may be urged through intake 1604 at pressure by pump assembly 30. In some embodiments, cooling liquid 200 may be urged through intake 1604 into outflow channel 24 at a rate between approximately 500-2000 gallons per minute. In some embodiments, this rate may be approximately 1500 gallons per minute. This establishes a current to facilitate flow of cooling liquid 200 towards open end 28 and to control the speed of flow. In some embodiments, intake 1604 may be omitted. In such embodiments, the flow of cooling liquid 200 in outflow channel 24 is substantially gravity-powered and intake 1604 may be omitted.

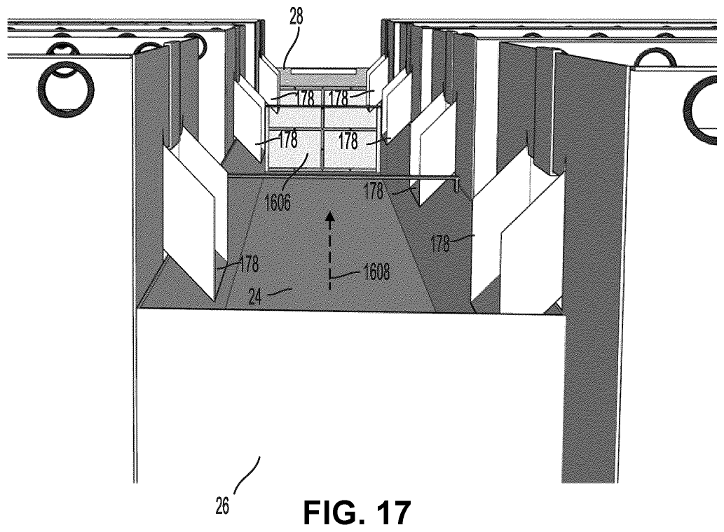

As depicted in FIG. 17, end 28 includes a filter 1606 for filtering out debris and other unwanted elements. Filter 1606 does not significantly impede flow of cooling liquid 200, yet blocks solids and contaminants such as flux released from electronic devices 50. In some embodiments, filter 1606 may be a mesh or screen filter made of materials which are substantially inert in the presence of cooling liquid 200. In some embodiments, such materials may include suitable metals, rubbers, plastics, or the like.

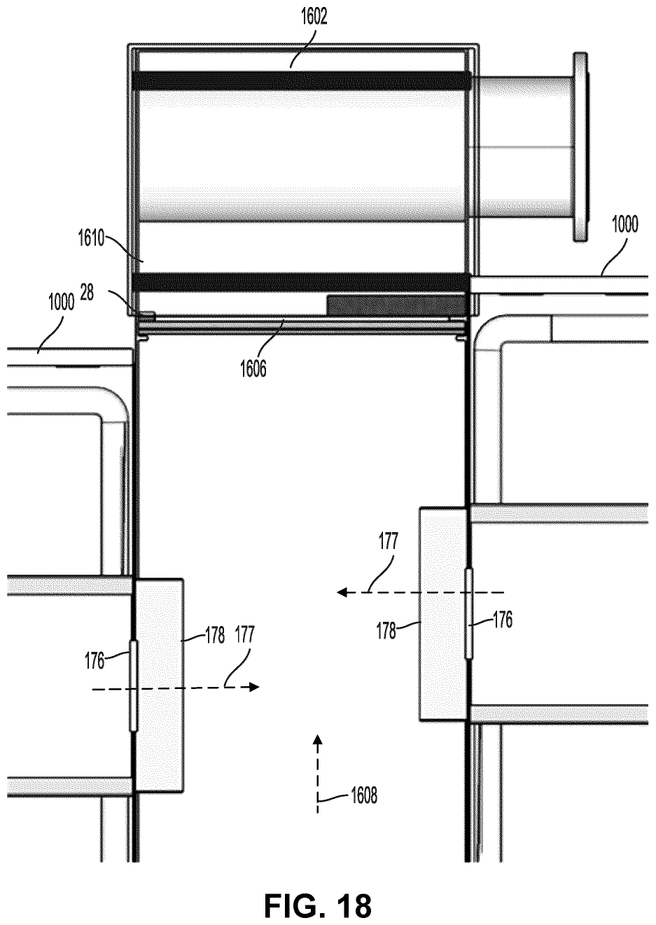

As depicted in FIG. 18, end 28 includes an outtake 1602. Outtake 1602 includes a sump 1610 for receiving cooling liquid 200 flowing past filter 1606. Sump 1610 includes a bottom opening for flow of cooling liquid 200 towards a downstream heat exchanger system (e.g., cooler 40).

Referring again to FIG. 17, during operation, cooling liquid 200 flows out of each immersion cooling system 1000 through opening 176 and down lip 178 in direction 177. Cooling liquid 200 from each immersion cooling system 1000 flows along outflow channel 24 in direction 1608 towards end 26. Cooling liquid 200 passes through filter 1606 into outtake 1602. Cooling liquid 200 flows into outtake 1602 and then flows via its downward opening towards downstream processing.

Conveniently, in the depicted embodiment, no mechanical connection between immersion cooling systems 1000 and outflow channel 24 is required. Further, in the depicted embodiment, no mechanical connection is between any of the immersion cooling systems 1000 is required. This allows tanks 100 to be readily swapped in and out, e.g., without need for mechanical disconnection/connection relative to outflow channel 24.

In the depicted embodiment, trough 174 and outflow channel 24 each has an open top. In some embodiments, the top of one or both of trough 174 and outflow channel 24 may be covered, e.g., to provide protection from debris and other unwanted elements. In some embodiments, the covered top may providing a working surface and/or a walking surface atop of trough 174 and/or outflow channel 24.

In some embodiments, outflow channel 24 may be formed as a pipe or other enclosed channel. In such embodiments, a trough 174 may feed cooling liquid 200 into outflow channel 24 by way of an opening in outflow channel 24 or by way of interconnected piping.

In the depicted embodiment, outflow channel 24 has a bottom surface that is substantially parallel to the ground. In some embodiments, the bottom surface of outflow channel 24 may be sloped to bias flow of cooling liquid 200 towards end 28. In some embodiments, the angle of this slope may be between approximately 5 and 10 degrees.

In the depicted embodiment, tank arrangement 20 includes seven immersion cooling system 1000. However, it will be appreciated that in other deployments, the number of immersion cooling system 1000 may vary.

In some embodiments, an advantage provided by the fluid flow architecture disclosed herein (e.g., with troughs 174 serving as “tributaries” feeding into a “river” at outflow channel 24) is that tank arrangement 20 and immersion cooling facility 10 may be readily scaled to a large number of immersion cooling systems 1000. For example, outflow channel 24, may be extended in length to accommodate a greater number of immersion cooling systems 1000. Further, the hierarchical organization of the fluid flow architecture may be extended such that multiple outflow channels 24 feed into a yet higher-level channel.

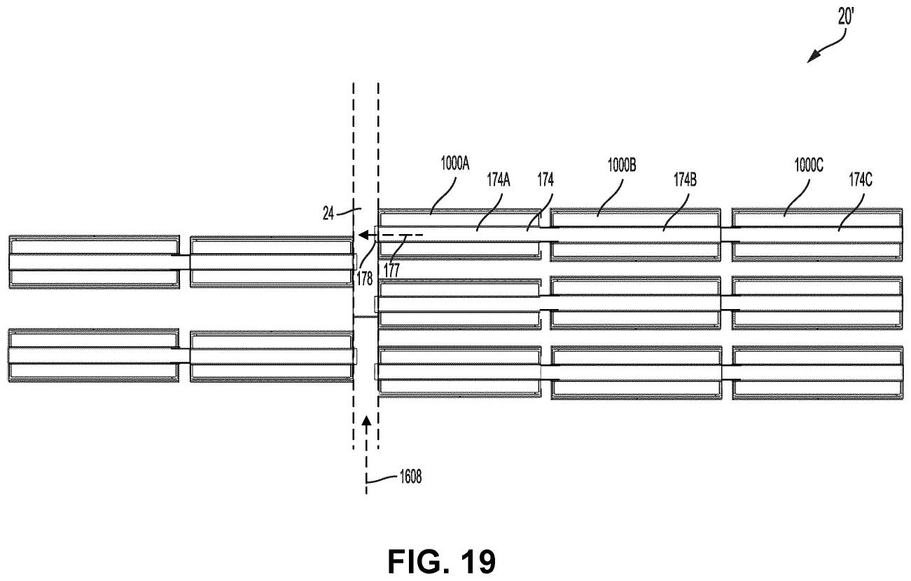

FIG. 19 depicts a portion of an immersion cooling facility 10 with a tank arrangement 20′, in accordance with an embodiment.

In tank arrangement 20′, a plurality of immersion cooling systems 1000 may be arranged end-on-end, e.g., in a direction approximately orthogonal to outflow channel 24. As depicted, immersion cooling systems 1000A, 1000B, and 1000C are arranged end-on-end. So arranged, immersion cooling systems 1000A, 1000B, and 1000C share a common trough 174. Common trough 174 includes cascading portions, namely trough portion 174A (extending along immersion cooling system 1000A), trough portion 174B (extending along immersion cooling system 1000B), and trough portion 174C (extending along immersion cooling system 1000C). During operation, trough 174C receives cooling liquid 200 flowing from immersion cooling system 1000C, which then flows into trough 174B. Trough 174B also receives cooling liquid 200 flowing from immersion cooling system 1000B. The cooling liquid 200 in trough 174B flows into trough 174A. Trough 174A also receives cooling liquid 200 flowing from immersion cooling system 1000A. The cooling liquid 200 in trough 174A flows into outtake channel 24 via lip 178. In this cascading fashion, cooling liquid 200 from each of immersion cooling systems 1000A, 1000B, and 1000C flows into outtake channel 24 in a direction 177 via a shared trough 174. This “serial” arrangement of immersion cooling systems 1000A, 1000B, and 1000C may be combined with the parallel of arrangement of immersion cooling systems as discussed in connection with FIG. 16, which further increases the number of tanks within a tank arrangement. The number of immersion cooling systems 1000 that can be connected serially may be fewer than three (e.g., two as shown) or greater than three.

Tank arrangement 20′ is otherwise substantially similar to tank arrangement 20. For example, immersion cooling systems 1000 of tank arrangement 20′ all dispense cooling liquid 200 into outtake channel 24.

FIG. 20A is a perspective view of trough portions 174A, 174B, and 174C (with each immersion cooling system 1000 shown to only include one tank 100), in accordance with an embodiment. FIG. 20B is a magnified view of region 2000 of FIG. 20A. As depicted, trough portion 174A and 174B are joined by a sloping portion 2002 that allows cooling liquid 200A to flow from trough portion 174B into trough portion 174A. Trough portions 174B and 174C are similarly joined.

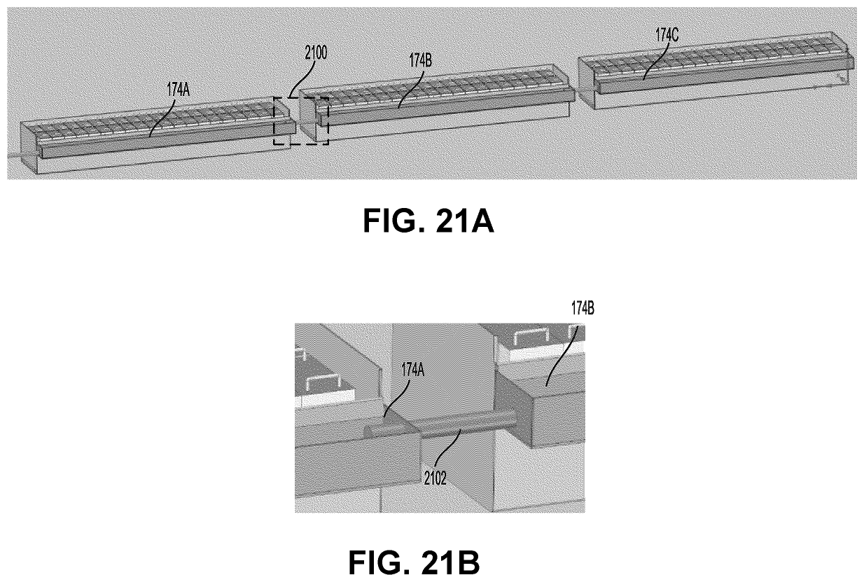

FIG. 21A is a perspective view of trough portions 174A, 174B, and 174C (with each immersion cooling system 1000 shown to only include one tank 100), in accordance with another embodiment. FIG. 21B is a magnified view of region 2100 of FIG. 20A. As depicted, trough portion 174A and 174B are joined by a pipe 2102 that allows cooling liquid 200A to flow from trough portion 174B into trough portion 174A.

Trough portions 174B and 174C are similarly joined.

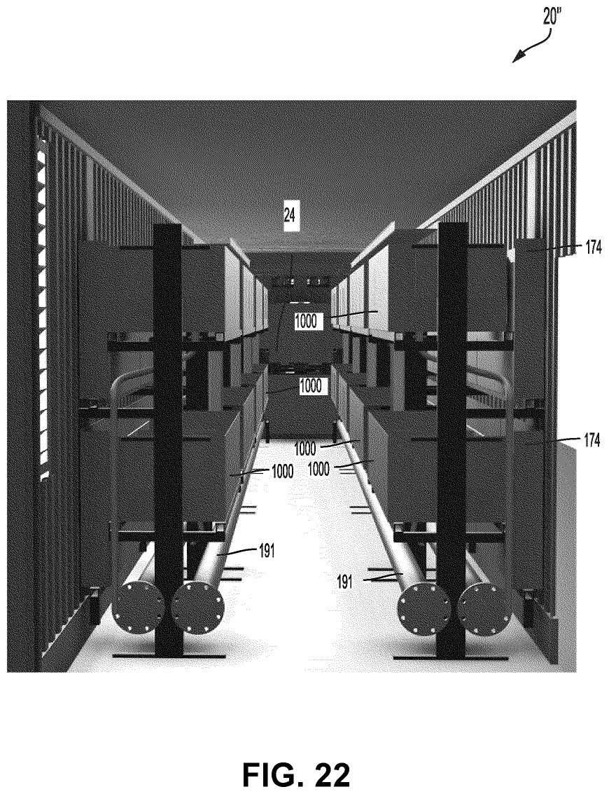

FIG. 22 depicts a portion of an immersion cooling facility 10 with a tank arrangement 20″, in accordance with an embodiment. Tank arrangement 20″ includes four sets of immersion cooling system 1000. Each set includes four immersion cooling systems 1000 (each with one tank 100) connected in series (in manner described above) with a common trough 174. As depicted, sets of the immersion cooling systems 1000 are stacked vertically so that a upper right set is above a lower right set, and a upper left set is above a lower left set.

Tank arrangement 20″ is otherwise substantially similar to tank arrangement 20. For example, immersion cooling systems 1000 of tank arrangement 20″ all dispense cooling liquid 200 into outtake channel 24.

In some embodiments, tank arrangement 20″ may be sized and configured to fit within a common shipping container (e.g., 8 feet×20 feet or 8 feet×40 feet).

Tank 100 may be sized to fit a plurality of electronic devices 50. In the depicted embodiments, tank 100 is sized to provide a width that accommodates a width of a hanger 150 that rests on top of side walls 106 and 108, where the width of hanger 150 is in turn sized to fit one or more electronic devices 50. In the depicted embodiments, tank 100 is sized to provide a height (or depth) to accommodate a height of electronic devices 50 and to allow placement at a desired vertical position. In the depicted embodiments, tank 100 is sized to provide a length L (FIG. 3) to accommodate a plurality of electronic devices 50. Tank 100 may be sized to accommodate any number electronic devices 50 along length L (e.g., 10, 20, 50, or more). In one example embodiment, tank 100 is approximately 1 meter in width, approximately 3 meters in length, and approximately 1 meter in height (depth).

Tank 100 is formed of metals (e.g., stainless steel, aluminum, or the like) and/or other materials (e.g., plastics, resins, or the like) having suitable strength and stiffness to support the mechanical load of both cooling liquid 200 and suspended electronic devices 50. Tank 100 is formed of materials (or materials having suitable coatings) to resist corrosion or damage caused by cooling liquid 200. Hangers 150 and pipe 191 may each be formed of similar materials.

Cooling liquid 200 is a conventional dielectric liquid such as Shell S3X dielectric liquid. In some embodiments, another liquid that is thermally conductive yet electrically substantially non-conductive may be used. In some embodiments, the liquid is also non-flammable. In some embodiments, a glycol such as ethylene glycol or propylene glycol, or a solution thereof, may be used. In some embodiments, a polyalphaolefin or similar synthetic oil may be used. In various embodiments, various suitable synthetic or natural hydrocarbons, or combinations thereof may be used. In some embodiments, deionized water may be used.

Of course, the above described embodiments are intended to be illustrative only and in no way limiting. The described embodiments are susceptible to many modifications of form, arrangement of parts, details and order of operation. The disclosure is intended to encompass all such modification within its scope, as defined by the claims.

1. An immersion cooling system for electronic devices, the system comprising:
a tank for immersion cooling of a plurality of electronic devices, the tank including:
an intake extending proximate a bottom of the tank, for dispensing cooling liquid into the tank;
an outtake extending along a top of the tank, for cooling liquid to exit the tank; and
wherein an electronic device is removably mountable at a position between the intake and the outtake to be immersed in the cooling liquid; and
a trough extending along the tank for receiving cooling liquid exiting the tank via the outtake.

2. The immersion cooling system of claim 1, wherein the tank is a first tank and the system further comprises a second tank oriented such that the trough extends along the first tank and the second tank, and wherein the cooling liquid exiting each of the first tank and the second tank is received in the trough.

3. The immersion cooling system of claim 2, wherein the trough extends between the first tank and the second tank.

4. The immersion cooling system of claim 2, wherein the outtake of the first tank is defined by a lip extending horizontally along the top of the first tank, whereby the cooling liquid exits the first tank by flowing over the lip.

5. The immersion cooling system of claim 4, the first tank and the second tank are oriented such that the lip of the first tank and a lip of the second tank are substantially parallel and meet at the trough.

6. The immersion cooling system of claim 1, wherein the trough slopes in a direction substantially parallel to the outtake of the tank.

7. The immersion cooling system of claim 2, wherein the trough includes a first trough portion extending along the first tank and a second trough portion extending along the second tank.

8. The immersion cooling system of claim 7, the first trough portion is configured to cascade flow of the cooling liquid into the second trough portion.

9. The immersion cooling system of claim 7, wherein a pipe extends between the first trough portion and the second trough portion for flow of the cooling liquid therein.

10. An immersion cooling facility comprising:
a first immersion cooling system as claimed in claim 1;
a second immersion cooling system as claimed claim 1; and
an outflow channel disposed to receive the cooling liquid from the trough of the first immersion cooling system, to be joined with the cooling liquid from the trough of the second immersion cooling system, the outflow channel providing a flow path for the joined cooling liquid to a cooler for cooling the cooling liquid.

11. The immersion cooling facility of claim 10, wherein a single cooler removes heat out of the cooling liquid from the first immersion cooling system and the cooling liquid from the second immersion cooling system.

12. The immersion cooling facility of claim 10 wherein the outflow channel extends between the first immersion cooling system and the second immersion cooling system.

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. The immersion cooling system of claim 1, the system further comprising:
a first intake feed for urging cooling liquid into the intake in a first direction; and
a second intake feed for urging cooling liquid into the intake in a second direction opposing the first direction;
wherein convergence of cooling liquid urged into the intake by the first and second intake feeds improves uniformity of pressure among the inlets of the intake.

27. The immersion cooling system of claim 26, wherein the intake forms a loop.

28. The immersion cooling system of claim 27, wherein the loop extends below the tank.

29. The immersion cooling system of claim 27, wherein the loop extends below the tank and at least one other tank.

30. The immersion cooling system of claim 27, wherein the loop extends below the tank and at least two other tanks.

31. The immersion cooling system of claim 26, wherein the intake includes a pipe and the first intake feed is for urging cooling liquid in a first end of the pipe, and the second intake feed is for urging cooling liquid in a second end of the pipe.

32. The immersion cooling system of claim 1, wherein the tank further comprises a diffuser for conditioning flow of the cooling liquid between the intake and the position of the electronic device.

33. The immersion cooling system of claim 32, wherein the diffuser establishes a tortuous path for flow of the cooling liquid from the intake to the position of the electronic device.
